(19) United States
(12) Patent Application Publication
(10) Pub. No.: US 2025/0025981 A1
(43) Pub. Date: Jan. 23, 2025

(54) DEVICE, METHOD, AND SYSTEM FOR TRANSFORMING MEASUREMENT DATA

(71) Applicant: SAMSUNG ELECTRONICS CO., LTD., Suwon-si (KR)

(72) Inventors: Hojoon Lee, Suwon-si (KR); Jinuk Byun, Suwon-si (KR); Joongsuk Oh, Suwon-si (KR); Seongryeol Kim, Suwon-si (KR); Younggu Kim, Suwon-si (KR); Seunghoon Choi, Suwon-si (KR); Jaemyung Choe, Suwon-si (KR)

(21) Appl. No.: 18/647,240

(22) Filed: Apr. 26, 2024

(30) Foreign Application Priority Data
Jul. 20, 2023 (KR) 10-2023-0094650
Sep. 11, 2023 (KR) 10-2023-0120489

(51) Int. Cl. B24B 37/005

(52) U.S. Cl. CPC B24B 37/005

(57) ABSTRACT

The present disclosure relates to devices, methods, and systems for transforming measurement data. An example device for transforming measurement data includes a communicator configured to receive first measurement data, the first measurement data including step height values on a semiconductor chip with a chemical mechanical polishing (CMP) process performed thereon, and to receive layout data comprising a layout included in the semiconductor chip, and a processor configured to, based on the layout data, transform the first measurement data to second measurement data, the second measurement data including step height values of the semiconductor chip with a metal deposited thereon.

### CROSS-REFERENCE TO RELATED APPLICATIONS

This application claims priority under 35 U.S.C. § 119 to Korean Patent Application Nos. 10-2023-0094650, filed on Jul. 20, 2023 and 10-2023-0120489, filed on Sep. 11, 2023 in the Korean Intellectual Property office, the disclosure of which are incorporated by reference herein in their entirety.

### BACKGROUND

Metrology systems for verifying and monitoring semiconductor processes, and controlling verification operations and monitoring operations are under development. A metrology system may measure step heights of patterns included in a semiconductor chip by using various metrology methods. Weaknesses (for example, weak points) of semiconductor chips may be found by using data of step heights. For example, metrology methods of a metrology system may include a scanning electron microscope (SEM), a transmission electron microscope (TEM), an atomic force microscope (AFM), a white light interferometer (WLI), a patterned wafer geometry (PWG), etc. Because each metrology method has its own way of measuring and unique characteristics, each metrology method has advantages and disadvantages in terms of accuracy, cost, metrology speed, range, etc. An optical metrology method such as a PWG measures a relatively wide range compared to the TEM or the like, so the time required to measure the entire semiconductor chip by using the PWG metrology method is relatively less than that of other metrology methods. However, because this type of optical metrology methods is vulnerable to optical interference occurring in the lower layer (or pattern) of semiconductor chips, there may be cases in which detection of vulnerabilities in the semiconductor chips is difficult.

To remove optical interference while obtaining data of step heights in the entire large-area semiconductor chip, an additional process of depositing a metal on a semiconductor chip, in which a chemical-mechanical polishing (CMP) process has been completed, may be required. A requirement to find the optimal thickness (or amount) of metal deposition causes the wafer to no longer be available, considerable consumption of additional process time, and a destructive analysis, and thus, issues such as an increase in manufacturing cost occur. Accordingly, technology is being studied to obtain data of optical metrology of a step height of the entire semiconductor chip without actually depositing a metal.

### SUMMARY

The present disclosure relates to devices, methods, and systems for predicting data with an optical interference effect on raw data removed by using an artificial intelligence model without destructive analysis.

In some implementations, a device for transforming measurement data includes a communicator configured to receive first measurement data including step height values optically measured in units of a target region on a first semiconductor chip with a chemical mechanical polishing (CMP) process performed on the first semiconductor chip, and receive layout data including a layout included in the first semiconductor chip, and a processor configured to, based on the layout data, generate density data including an image, to which layout density indicating a ratio of area occupied by the layout in a unit resolution region is applied, input the density data and the first measurement data to an artificial intelligence model, and predict, as an output of the artificial intelligence model, second measurement data including step heights per target region of a second semiconductor chip comprising the first semiconductor chip and a metal deposited on the first semiconductor chip.

In some implementations, a method of transforming measurement data includes receiving first measurement data including step height values optically measured in units of a target region on a first semiconductor chip with a chemical mechanical polishing (CMP) process performed on the first semiconductor chip, and receiving layout data including a layout included in the first semiconductor chip, generating density data including an image to which layout density indicating a ratio of area occupied by the layout in a unit resolution region is applied, and by using an artificial intelligence model, predicting, from the density data and the first measurement data, second measurement data including step height values per the target region of a second semiconductor chip comprising the first semiconductor chip and a metal deposited on the first semiconductor chip.

In some implementations, a system includes an optical measurement device configured to generate first measurement data including step height values of a first semiconductor chip, by optically measuring the first semiconductor chip with a chemical mechanical polishing (CMP) process performed thereon in units of the target region, a database storing layout data including a layout included in the first semiconductor chip, and a measurement data transformation device configured to transform the first measurement data to second measurement data including step height values of a second semiconductor chip comprising the first semiconductor chip and a metal deposited on the first semiconductor chip, based on the first measurement data, the layout data, and an artificial intelligence model.

In some implementations, a method includes performing a chemical mechanical polishing (CMP) process on a first semiconductor chip, generating first measurement data including step height values of the first semiconductor chip, by optically measuring the first semiconductor chip in units of a target region, transforming the first measurement data to second measurement data including step height values of a second semiconductor chip comprising the first semiconductor chip and a metal deposited on the first semiconductor chip, based on layout data stored in a database, the first measurement data, and an artificial intelligence model, and detecting a weak point in the first semiconductor based on the second measurement data.

### BRIEF DESCRIPTION OF THE DRAWINGS

Implementations will be more clearly understood from the following detailed description taken in conjunction with the accompanying drawings.

FIG. 1 is a block diagram of an example of a system.

FIG. 2 is an example graph of an inspection range and capability of weak point detection according to a metrology method of a metrology device in FIG. 1.

FIG. 3 illustrates example diagrams of first measurement data and second measurement data.

FIG. 4 is an example diagram of step heights of first measurement data and second measurement data.

FIG. 5 illustrates example diagrams of step information and measurement accuracy of semiconductor chips according to the amount of metal deposition.

FIG. 6 is a block diagram of an example of a measurement data transformation device.

FIG. 7 is a flowchart explaining an example of a measurement data transformation method.

FIG. 8 illustrates diagrams of example implementations for removing noise from measurement data.

FIG. 9 illustrates example diagrams of layout data and density data.

FIG. 10 illustrates an example graph of layout density of each of a first layout and a second layout.

FIG. 11 is an example diagram of an input and an output of an artificial intelligence model.

FIG. 12 is a diagram illustrating an example of an artificial intelligence model.

FIG. 13 is an example graph of step heights of a semiconductor chip with a metal deposited thereon.

FIG. 14 is an example graph of step heights of a semiconductor chip with a metal deposited thereon and predict values of an artificial intelligence model.

FIG. 15 illustrates diagrams for explaining an example of a learning process of an artificial intelligence model.

FIG. 16 is an example diagram of a root mean squared error (RMSE) and an r-squared (R2) score according to a learning process of the artificial intelligence model of FIG. 15.

FIG. 17 illustrates example diagrams for explaining an implementation of removal of noise from measurement data in a learning process of an artificial intelligence model in FIG. 15.

FIGS. 18 and 19 are example diagrams for explaining test results of an artificial intelligence model.

FIG. 20 illustrates example diagrams of weak points.

### DETAILED DESCRIPTION

Hereinafter, implementations of the present disclosure will be described in detail with reference to the accompanying drawings.

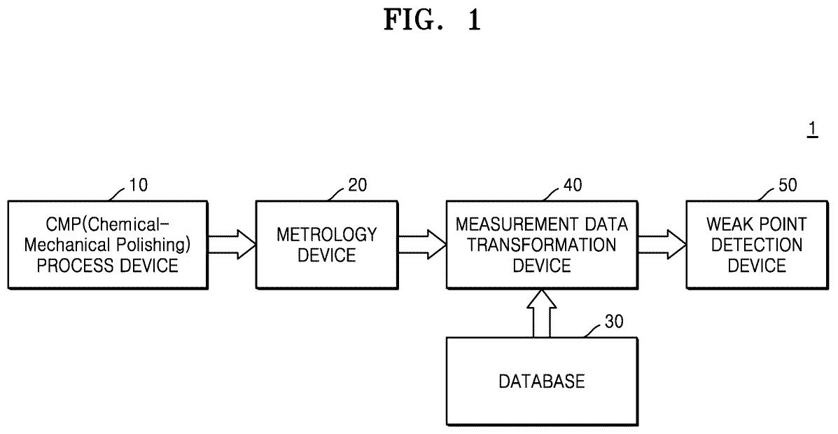

FIG. 1 is a block diagram of an example of a system 1.

Referring to FIG. 1, the system 1 may include a chemical mechanical polishing (CMP) process device 10, a metrology device 20, a database 30, a measurement data transformation device 40, and a weak point detection device 50.

The CMP process device 10 may perform the CMP process on a semiconductor chip. The CMP process may include a process of planarizing a wafer by polishing a film surface of the wafer, on which unevenness or bending occurs, by using a chemical element and a mechanical element. To this end, the CMP process device 10 may include a polishing head, a CMP slurry polishing pad, a rotating plate, a rotating head, a conditioner, a table, etc.

The metrology device 20 may measure a wafer on which the CMP process has been completed. A wafer may include a plurality of semiconductor chips. In some implementations, the metrology device 20 may optically measure each semiconductor chip on which the CMP process has been performed. For example, the metrology device 20 may generate first measurement data by optically measuring the first semiconductor chip, on which the CMP process has been performed, in units of the target region. The time required to optically measure the first semiconductor chip, for example, the measurement turnaround time (TAT), may be less than about 1 minute, but is not limited thereto. In this case, the target region may be an optical measurement unit of the metrology device 20. For example, a shape of the target region may be rectangular, and a size of the target region may be about 40 μm*about 40 μm, but is not limited thereto. In this case, a length of one side of the target region (for example, about 40*μm) may be referred to as resolution. Because a size of the first semiconductor chip is greater than a size of the target region, the first semiconductor chip may include a plurality of target regions. First measurement data may include scalar data and image data. The scalar data may include a step height of a target region on the first semiconductor chip. For example, the scalar data may include a step height per target region of the entire first semiconductor chip, that is, step heights of the target regions. The image data may include an image in which the step heights of the target regions in the first semiconductor chip are respectively represented in different colors. The number of step heights included in one semiconductor chip may be about 500,000, but is not limited thereto. The metrology device 20 may provide the first measurement data to the measurement data transformation device 40.

The database 30 may store layout data including a layout included in each semiconductor chip included in the wafer. In some implementations, the database 30 may store layout data including a layout included in each semiconductor chip included in the wafer. The database 30 may provide the layout data to the measurement data transformation device 40.

The measurement data transformation device 40 may transform the first measurement data to second measurement data, based on the first measurement data, the layout data, and an artificial intelligence model. The second measurement data may include data predicted by the artificial intelligence model. The second measurement data may include the scalar data and the image data. The scalar data included in the second measurement data may include a step height optically measured in units of the target region on a second semiconductor chip, and for example, the scalar data included in the second measurement data may include step heights of the second semiconductor chip. The image data included in the second measurement data may include an image in which the step heights of the target regions in the second semiconductor chip are respectively represented in different colors. The second semiconductor chip may include the first semiconductor chip with a metal deposited on the first semiconductor chip.

In some implementations, the measurement data transformation device 40 may generate layout density indicating a ratio of an area occupied by the layout in a unit resolution region, and predict the second measurement data from the density data and the first measurement data by using the artificial intelligence model.

In some implementations, the measurement data transformation device 40 may input the first measurement data and the density data, from which noise has been removed, to the artificial intelligence model, by removing noise from raw data of the first measurement data by using a noise removal algorithm.

In some implementations, the measurement data transformation device 40 may input, to the artificial intelligence model, the first measurement data including one step height optically measured in one target region and a plurality of pieces of density data including image of each of different layouts.

In some implementations, through supervised learning, the measurement data transformation device 40 may train the artificial intelligence model with a learning data set including the first measurement data, the density data, and the second measurement data.

The weak point detection device 50 may detect a weak point in a first semiconductor based on the second measurement data. A weak point may be referred to as a weak location, a hot spot, etc.

A method performed by the system 1 may include performing, by the CMP process device 10 the CMP process on the first semiconductor chip, generating by the metrology device 20 the first measurement data including step heights of the first semiconductor chip by optically measuring the first semiconductor chip in units of the target region, transforming by the measurement data transformation device 40 the first measurement data to the second measurement data based on the layout data stored in the database 30, the first measurement data, and the artificial intelligence model, and detecting by the weak point detection device 50 the weak point from the first semiconductor based on the second measurement data.

In some implementations, the cost and time required for the destructive analysis may be reduced by generating data with optical interference effects removed therefrom by using an artificial intelligence model without the destructive analysis on a semiconductor chip.

In addition, in some implementations, by using the artificial intelligence model having learned information about the layer of a semiconductor chip affecting the light interference, information about step heights of a semiconductor chip may be obtained without actually depositing a metal on the semiconductor chip, process operations may be simplified, and the time and cost of the model may be reduced.

In addition, in some implementations, by obtaining information about the step heights of the semiconductor chip without actually depositing a metal on the semiconductor chip, the weak points of the semiconductor chip may be promptly detected.

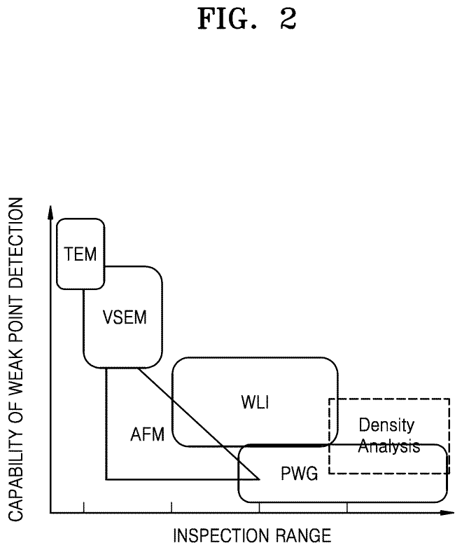

FIG. 2 is an example graph of an inspection range and capability of weak point detection according to a metrology method of the metrology device 20 in FIG. 1.

Referring to FIGS. 1 and 2, the metrology device 20 may measure a wafer by using any one metrology method among various metrology methods. The various metrology methods may include, for example, a transmission electron microscope (TEM), a vertical scanning electron microscope (VSEM), an atomic force microscope (AFM), a white light interferometer (WLI), a patterned wafer geometry (PWG), density analysis, a digital holographic microscope (DHM), a scanning electron microscope (SEM), etc. However, the implementation is not limited thereto. These metrology methods may have the capability of performing weak point detection with respect to an inspection range. For example, in the case of the TEM among the metrology methods illustrated in FIG. 2, the inspection range may be the least and the capability of weak point detection may be the greatest. For example, in the case of the PWG among the metrology methods illustrated in FIG. 2, the inspection range may be the greatest and the capability of weak point detection may be the least. Because the PWG metrology method may not only measure wafer displacement referred to as warpage but adjust the entire displacement by measuring both surfaces of a wafer, the PWG metrology method may measure parameters, such as displacement in a plan view, local curvature, and surface change in a short time (for example, less than about 1 minute).

The PWG metrology method may include a method of optically measuring a geometric shape of a patterned wafer. The PWG metrology method may measure the entire semiconductor chip compared to other metrology methods (for example, the TEM method). In some implementations, when the metrology method of the metrology device 20 is a PWG method, the metrology device 20 may generate measurement data including all measurement values of each semiconductor chip, for example, the first measurement data.

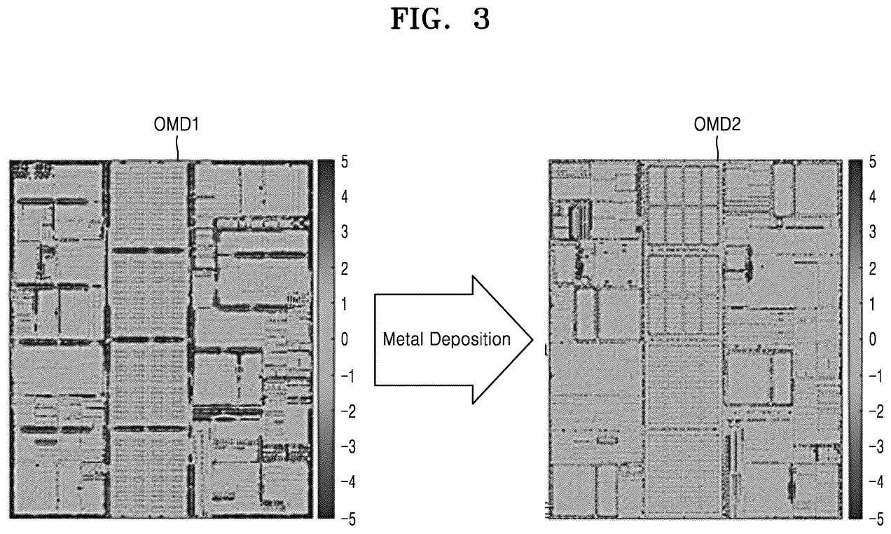

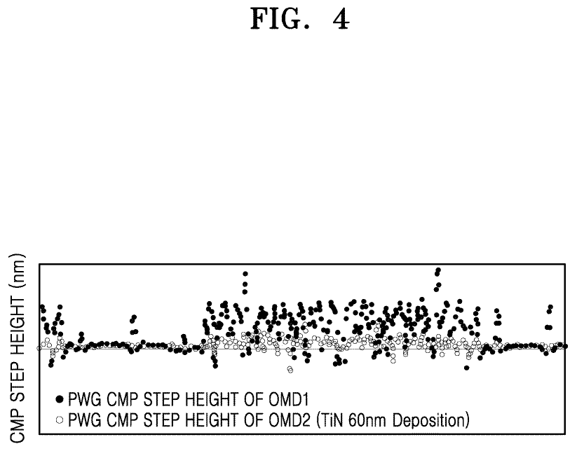

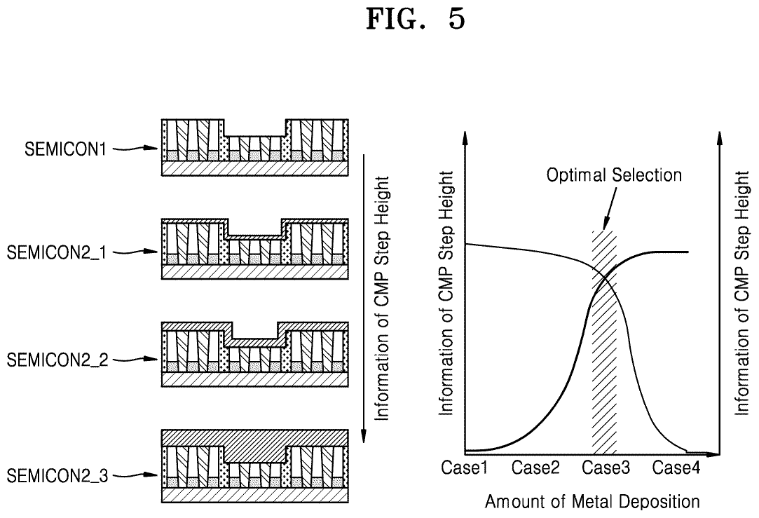

FIG. 3 illustrates example diagrams of first measurement data OMD1 and second measurement data OMD2. FIG. 4 is an example diagram of step heights of the first measurement data OMD1 and the second measurement data OMD2. FIG. 5 illustrates example diagrams of step information and measurement accuracy of semiconductor chips according to the amount of metal deposition.

Referring to FIGS. 1, 3, and 4, the first measurement data OMD1 may be generated according to the PWG metrology method performed by the metrology device 20. The first measurement data OMD1 may include an image indicating the layout of the entire semiconductor chip, in which step heights are represented in color. In this case, each step may occur in one semiconductor chip where the CMP process has been performed. Referring to FIG. 4, for example, step heights included in the first measurement data OMD1 (for example, refer to ‘PWG CMP STEP HEIGHT OF OMD1’ in FIG. 4) may have high variability. According to the PWG metrology method, optical interference of a silicon (Si) membrane included in the semiconductor chip due to a lower membrane may occur. In other words, because optical interference occurs in the first measurement data OMD1, which is generated by the PWG metrology method, when a user uses the first measurement data OMD1 to perform a quantitative analysis on step heights of a wafer, the quantitative analysis may be difficult to be performed due to the optical interference.

A method of removing the optical interference may be performed by depositing a metal on a wafer and optically measuring a semiconductor chip included in a wafer with a metal deposited thereon. In other words, the second measurement data OMD2 obtained by optically measuring a semiconductor chip with a metal deposited thereon may be available. Referring to FIG. 4, it is assumed that, for example, the metal includes titanium nitride (TiN), and the amount of the metal deposition is about 60 nm. Step heights included in the second measurement data OMD2 (for example, refer to ‘PWG CMP STEP HEIGHT OF OMD2’) may have less variability. However, to measure with consistency the wafer with a metal deposited thereon, there may be an issue that destructive analysis is required.

On the other hand, referring to FIG. 5, first case Case1, second case Case2, third case Case3, and fourth case Case4 may illustrate example cross-sections of a semiconductor chip having a different amount of metal deposition for each case. It is illustrated that the number of cases is four in FIG. 5, but this is an example. The first case Case1 may illustrate a portion of the cross-section of a semiconductor chip without a metal deposited thereon. The semiconductor chip without a metal deposited thereon may be referred to as a first semiconductor chip SEMICON1 in the present disclosure. The second case Case2, third case Case3, and fourth case Case4 may illustrate portions of the cross-sections of the semiconductor chip without a metal deposited thereon. The semiconductor chip with a metal deposited thereon may be referred to as second semiconductor chips SEMICON2_1, SEMICON2_2, or SEMICON2_3 in the present disclosure. When a metal is not deposited on a semiconductor chip as in the first case Case1, step information of the semiconductor chip may be relatively accurate, but the measurement accuracy of the PWG metrology method may be relatively low. On the other hand, when a metal is excessively deposited on the semiconductor chip as in the fourth case Case4, the measurement accuracy of the PWG metrology method may be relatively high, but although a step actually occurs in the semiconductor chip, the step information about the semiconductor chip may be relatively measured low and inaccurate. Accordingly, an optimal value may need to be analyzed like in the third case Case3. In other words, a method of predicting the second measurement data OMD2 by using an artificial intelligence model may be required instead of actually depositing a metal to avoid destructive analysis. In addition, it may be required for the second measurement data OMD2 predicted by the artificial intelligence model to have a step measured in the semiconductor chip with a metal deposited thereon with an optimal amount of metal deposition.

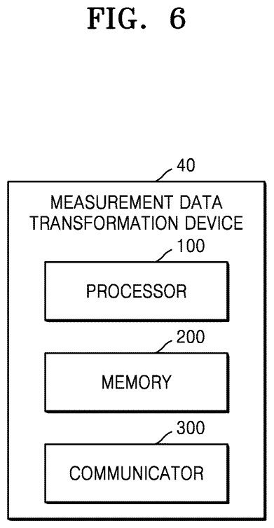

FIG. 6 is a block diagram of an example of the measurement data transformation device 40.

Referring to FIG. 6, the measurement data transformation device 40 in the present disclosure may include all of various devices capable of providing results of performing calculation processes to a user. For example, the measurement data transformation device 40 may include a computer, a server device, and/or a mobile terminal. In this case, the computer may include, for example, a notebook with a web browser installed thereon, a desktop, etc. The server device may include a server processing information by communicating with an external device, and may include an application server, a computing server, a web server, etc. The mobile terminal may include all types of handheld-based wireless communication devices, such as a personal communication system (PCS), a personal digital cellular (PDC), and a smartphone.

The measurement data transformation device 40 may include a device for transforming the measurement data. The measurement data transformation device 40 may include a processor 100, a memory 200, and a communicator 300.

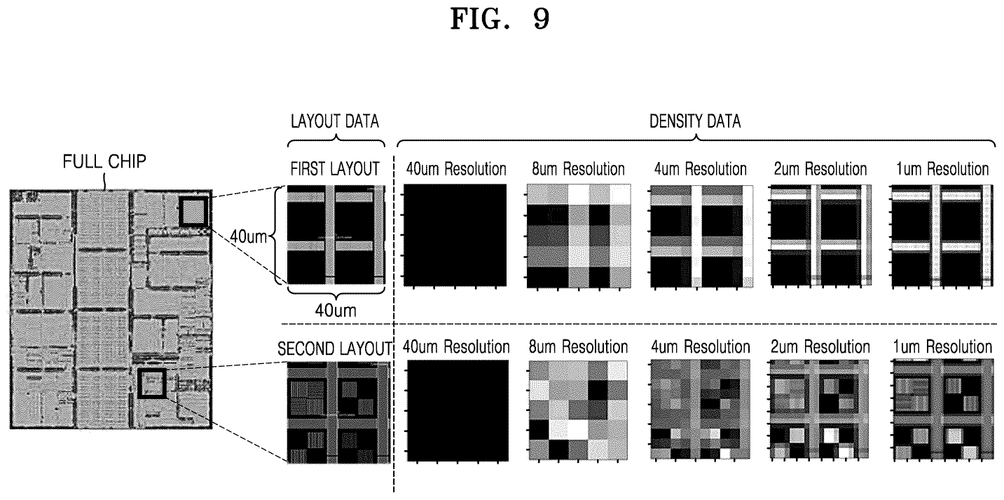

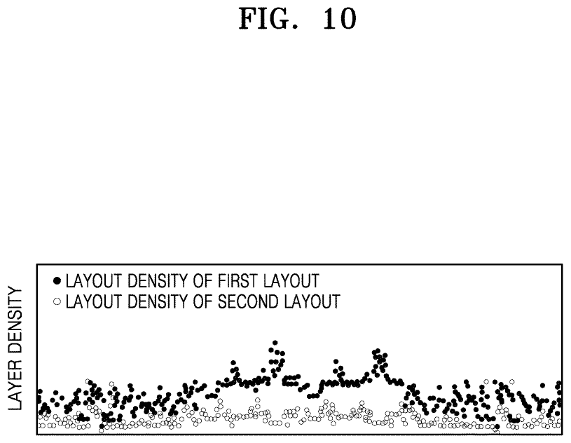

The processor 100 may generate the density data based on the layout data. The layout data may include data stored in the database 30 in FIG. 1. The processor 100 may obtain the layout data from the database 30 in FIG. 3. The density data may include an image to which the layout density indicating a ratio of area occupied by the layout in the unit resolution region is applied. The density data is described below with reference to FIGS. 9 and 10. The processor 100 may input the density data and the first measurement data to the artificial intelligence model, and predict the second measurement data as an output of the artificial intelligence model. The second measurement data may include at least one step height optically measured in units of the target region on the second semiconductor chip. The second semiconductor chip may include the first semiconductor chip with a metal deposited thereon.

Functions related to an artificial intelligence according to the present disclosure may be operated by using the processor 100 and the memory 200. One or more processors 100 may include a general purpose processor, such as a central processing unit (CPU), an application processor (AP), and a digital signal processor (DSP), a graphics dedicated processor, such as a graphics processing unit (GPU) and a vision processing unit (VPU), or an artificial intelligence dedicated processor such as a neural processing unit (NPU). One or more processors 100 may process input data based on pre-defined operation rules or an artificial intelligence model stored in the memory 200. When one or more processors 100 include an artificial intelligence dedicated processor, the artificial intelligence dedicated processor may be designed in a hardware structure specialized for processing a particular artificial intelligence model.

The pre-defined operation rules or the artificial intelligence model may be obtained through learning. In this case, being obtained through learning may mean that the pre-defined operation rules or the artificial intelligence model is obtained for performing desired characteristics (or, purposes) through learning, by a base artificial intelligence model, using various pieces of learning data by applying a learning algorithm. The learning described above may be performed in a device itself, in which artificial intelligence is performed according to the present disclosure, and may also be performed by using a separate server and/or a system. Examples of learning algorithms may include supervised learning, unsupervised learning, semi-supervised learning, or reinforcement learning, but are not limited thereto.

The artificial intelligence model may include one artificial intelligence model, and may also include a plurality of artificial intelligence models. The artificial intelligence model may be comprised to a neural network (or artificial neural network), and may include a statistical learning algorithm which imitates biological neural network in machine learning and recognition science. The neural network may be referred to as the entire model, in which artificial neurons (nodes) forming a network by combining synapses change the binding strength of the synapses through learning to obtain problem-solving capabilities. The neurons of the neural network may include a combination of weights or biases. The neural network may include one or more layers including one or more neurons or nodes. As an example, the neural network may include an input layer, a hidden layer, and an output layer. The neural network may infer (or predict) a result to be predicted from an arbitrary input by changing a weight of the neuron through learning.

The processor 100 may generate a neural network, train (or learn) the neural network, perform computation based on received input data, generate an information signal based on the operation result, or retrain the neural network. Models of the neural network may include various kinds of models such as a convolution (C) neural network (NN) (CNN), such as GoogleNet, AlexNet, and VGG network, a region (R) with CNN (R-CNN), an R proposal network (RPN), a recurrent (R) NN (RNN), a stacking(S)-based deep NN (DNN) (SDNN), a state-space (SS) DNN (S-SDNN), a deconvolution network, a deep belief network (DBN), a restricted Boltzmann machine (RBM), a fully convolutional network, a long short-term memory (LSTM) network, and a classification network, but are not limited thereto. The neural network may also include DNN.

The NN may include CNN, RNN, perceptron, multilayer perceptron, feed forward (FF), radial basis function network (RBFN), deep feed forward (DFF), long short term memory (LSTM), a gated recurrent unit (GRU), an auto encoder (AE), an variational auto encoder (VAE), a denoising auto encoder (DAE), a sparse auto encoder (SAE), a Markov chain (MC), a Hopfield network (HN), a Boltzmann machine (BM), a restricted Boltzmann machine (RBM), a deep belief network (DBN), a deep convolutional network (DCN), a deconvolutional network (DN), a deep convolution inverse graphics neural network (DCIGN), a generative adversarial network (GAN), a liquid state machine (LSM), an extreme learning machine (ELM), an echo state network (ESN), a deep residual network (DRN), a differentiable neural computer (DNC), a neural turning machine (NTM), a capsule network (CN), a Kohonen network (KN), and an attention network (AN), but one of ordinary skill in the art should understand that the NN is not limited thereto and may include an arbitrary neural network.

The memory 200 may store data supporting various functions of the measurement data transformation device 40 and programs for operations of the processor 100, store input/output data (for example, a music file, a still image, a video, or the like), and store a plurality of application programs (or applications) operated by the measurement data transformation device 40, data and commands for operations of the measurement data transformation device 40. At least some of these application programs may be downloaded from an external server via wireless communication. The plurality of application programs may include various algorithms, for example, an artificial intelligence model, noise removal algorithm, etc.

The memory 200 may include at least one type of storage medium among a flash memory type, a hard disk type, a solid state disk (SSD) type, a silicon disk drive (SDD) type, a multimedia card micro type, a card type memory (for example, scan disk (SD), extreme digital (XD) memory, or the like), random access memory (RAM), static RAM (SRAM). read-only memory (ROM), electrically erasable programmable ROM (EEPROM), programmable ROM (PROM), magnetic memory, a magnetic disk, and an optical disk.

The communicator 300 may receive the first measurement data and the layout data including the layout included in the first semiconductor chip, and provide the first measurement data and the layout data to the processor 100. In some implementations, the communicator 300 may perform, as a communication interface, a function of a path between various types of external devices connected to the measurement data transformation device 40.

Although not illustrated, the measurement data transformation device 40 may further include a display unit for displaying a process result of the processor 100 and processed information. The display unit may display screen information about executing an application program driven by the measurement data transformation device 40, or a user interface (UI)/graphical user interface (GUI) according to the screen information under execution.

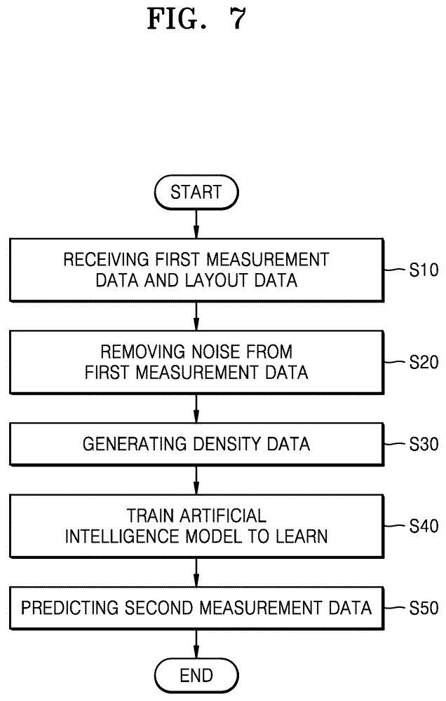

FIG. 7 is a flowchart explaining an example of a measurement data transformation method.

Referring to FIGS. 6 and 7, the measurement data transformation method may include a method performed by the measurement data transformation device 40.

In operation S10, the measurement data transformation device 40 may receive the first measurement data and the layout data. In some implementations, the measurement data transformation device 40 may receive the raw data of the first measurement data and the layout data including the layout included in the first semiconductor chip.

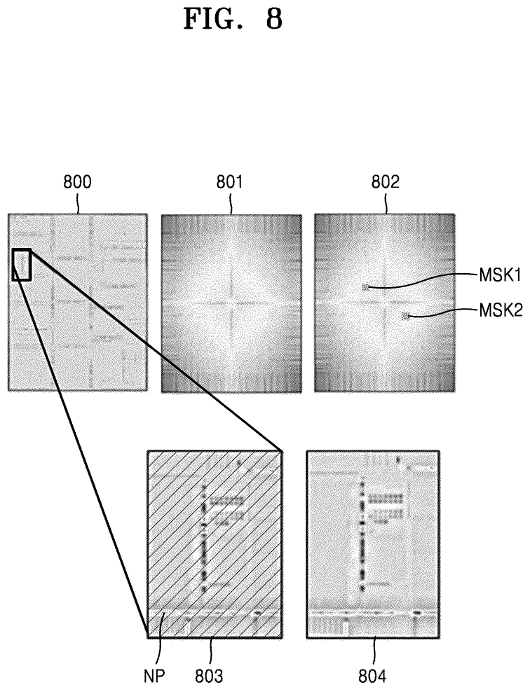

In operation S20, the measurement data transformation device 40 may remove noise from the first measurement data. In some implementations, the measurement data transformation device 40 may remove noise in the raw data of the first measurement data. In some implementations, the measurement data transformation device 40 may generate the first measurement data with noise removed therefrom, by removing noise from the raw data of the first measurement data by using the noise removal algorithm. The first measurement data with noise removed therefrom may be learned by the artificial intelligence model. In addition, the first measurement data with noise removed therefrom may be input to the learned artificial intelligence model. An implementation of removing noise is described below with reference to FIG. 8.

In operation S30, the measurement data transformation device 40 may generate the density data based on the layout data. The density data may include an image of the layout to which the layout density has been applied. The layout density may represent a ratio of an area occupied by the layout in the unit resolution region. In some implementations, the measurement data transformation device 40 may generate a plurality of density data including images of different layouts.

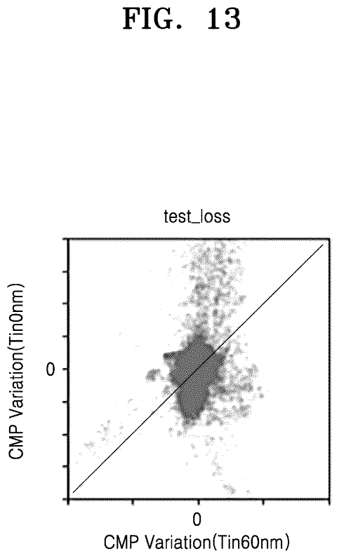

In operation S40, the measurement data transformation device 40 may train the artificial intelligence model with the learning data set. In some implementations, the measurement data transformation device 40 may train the artificial intelligence model to learn the learning data set including the first measurement data, the density data, and the second measurement data. The second measurement data may include an output of the artificial intelligence model. In some implementations, operation S40 may include, by using the noise removal algorithm, removing noise from first raw data of the first measurement data and noise from a second raw data of the second measurement data, setting the first and second measurement data and the density data with noise removed therefrom as the learning data set, and training the artificial intelligence model to learn the learning data set through supervised learning. Implementations of training the artificial intelligence model are described below with reference to FIGS. 13, 14, 15, and 16.

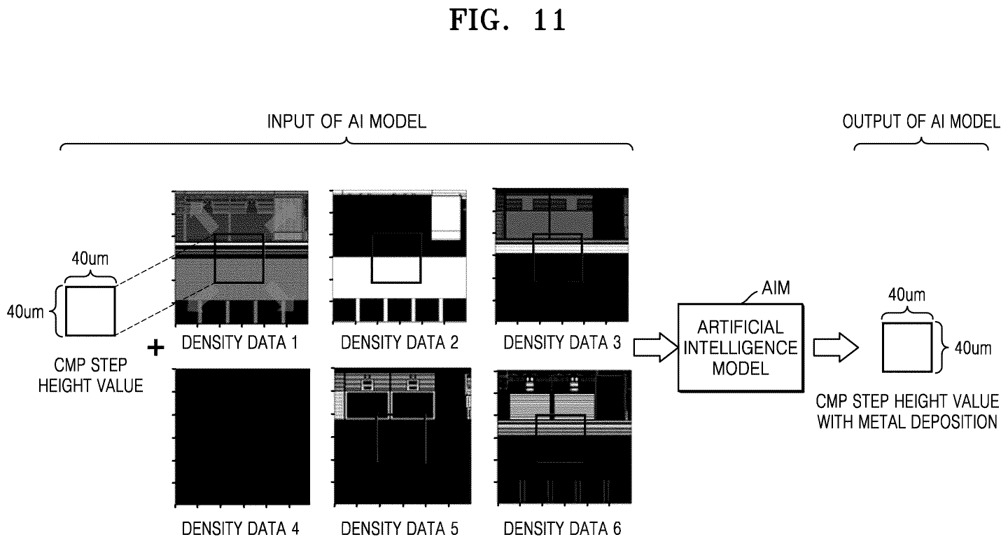

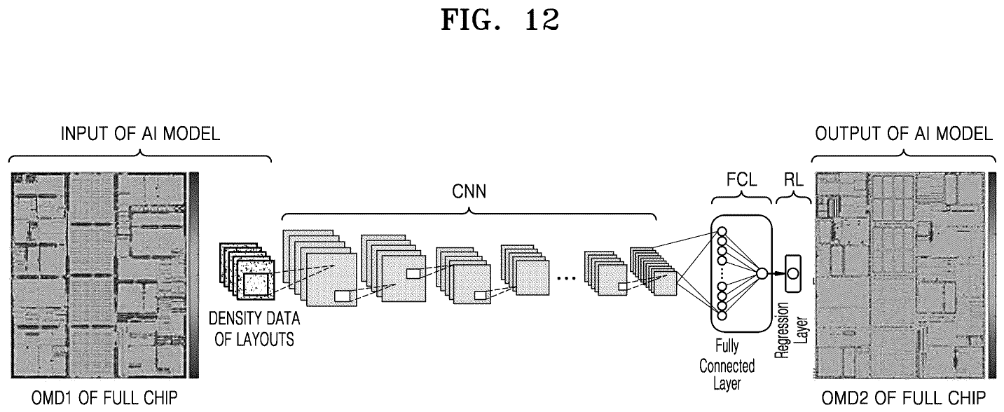

In operation S50, the measurement data transformation device 40 may predict the second measurement data from the density data and the first measurement data by using the artificial intelligence model. Implementations of operation S50 are described below with reference to FIGS. 11 and 12.

In some implementations, the cost and time required for the destructive analysis may be reduced by generating data with optical interference effects removed therefrom by using an artificial intelligence model without the destructive analysis on a semiconductor chip.

In addition, in some implementations, by using the artificial intelligence model having learned information about the layer of a semiconductor chip affecting the light interference, information about step heights of a semiconductor chip may be obtained without actually depositing a metal on the semiconductor chip, process operations may be simplified, and the time and cost of the model may be reduced.

In addition, in some implementations, by obtaining information about the step heights of the semiconductor chip without actually depositing a metal on the semiconductor chip, the weak points of the semiconductor chip may be promptly detected.

FIG. 8 illustrates diagrams of example implementations for removing noise from measurement data.

Referring to FIGS. 6 and 8, the processor 100 may receive raw data 800 of the first measurement data via the communicator 300. The raw data 800 may include the entire image of the first semiconductor chip as illustrated in FIG. 8.

The processor 100 may remove noise from the raw data 800 by using the noise removal algorithm. In some implementations, the noise removal algorithm may include fast Fourier transform (FFT). However, the implementation is not limited thereto. The processor 100 according to the implementation may change the domain of the raw data 800 to the frequency domain of the FFT by using the FFT. An FFT spectrum 801 with respect to the raw data 800 may be illustrated as in FIG. 8. The processor 100 according to the implementation may remove noise from the raw data 800 by reflecting at least one mask in the FFT spectrum 801. An FFT spectrum 802 included in the at least one mask may be generated as illustrated in FIG. 8. The FFT spectrum 802 in FIG. 8 may include a first mask MSK1 and a second mask MSK2. In this case, the mask may correspond to a zero pad having a value of about 0. The processor 100 according to the implementation may restore the frequency domain of the FFT to a domain. Referring to FIG. 8, for example, before the FFT is applied to a domain, a portion 803 of the raw data 800 may include a noise pattern NP having a diagonal line shape. In a portion 804 of the raw data 800 after the FFT is applied, the noise pattern NP may be removed. An R-squared R2 score for a step of the measurement data, from which noise has been removed, compared to a step of the raw data may increase.

The processor 100 may input the first measurement data with noise removed therefrom to the artificial intelligence model.

According to the implementations described above, by removing noise from the raw data, the predictability of the artificial intelligence model may be more accurately improved.

FIG. 9 illustrates examples of layout data LAYOUT DATA and DENSITY DATA. FIG. 10 illustrates an example graph of layout density of each of a first layout and a second layout.

Referring to FIGS. 9 and 10, the layout data may include an image of a particular layout included in a portion of a semiconductor chip FULL CHIP. For example, any one piece of layout data may include an image of the first layout included in a portion of the semiconductor chip FULL CHIP. The first layout may include at least one layer. The other piece of layout data may include an image of the second layout included in the other portion of the semiconductor chip FULL CHIP. The second layout may include the other at least one layer of the layer included in the first layout. The layout density may represent a ratio of an area occupied by a layout in the unit resolution region. The layout density of each of the first layout and the second layout is illustrated in FIG. 10. In FIG. 10, the value of the layout density may be referred to as a layer density. The size of the unit resolution region may be, for example, about 40 μm*about 40 μm, about 8 μm*about 8 μm, about 4 μm*about 4 μm, about 2 μm*about 2 μm, or about 1 μm*about 1 μm. However, the implementation is not limited thereto. The unit resolution region may be referred to as a region of a unit domain. The unit resolution or the unit domain may be about 40 μm*, about 8 μm, about 4 μm, about 2 μm, or about 1 μm. A size of an image or a size of the layout of the layout data is assumed to be about 40 μm*about 40 μm. When the unit resolution is about 40 μm resolution, because the unit resolution region is about 40 μm*about 40 μm, the density data may include an image of the 1*1 unit resolution regions. When the unit resolution is about 8 μm resolution, because the unit resolution region is about 8 μm*about 8 μm, the density data may include an image of the layout 5*5 unit resolution regions. When the unit resolution is about 4 μm resolution, the density data may include an image of the layout having 10*10 unit resolution regions. When the unit resolution is about 2 μm resolution, the density data may include an image of the layout having 20*20 unit resolution regions. When the unit resolution is about 2 μm resolution, the density data may include an image of the layout having 40*40 unit resolution regions.

As the unit resolution decreases, the time required for the artificial intelligence model to learn may increase. As the resolution decreases, the prediction accuracy of the artificial intelligence model may generally increase, but when a particular unit resolution increases higher than a certain value, the prediction accuracy of the artificial intelligence model may decrease. Thus, there may be an optimal value among the unit resolutions. The optimal value among the unit resolutions may be set during the learning process of the artificial intelligence model or when the learning of the artificial intelligence model is completed. For example, the optimal unit resolution may be about 2 μm resolution, but is not limited thereto.

In some implementations, as data preparation process before learning and application of the artificial intelligence model, normalization, outlier data augmentation, input layout domain selection (for example, domain of density data), unit size selection (for example, unit resolution), or the like may be performed.

In some implementations, the time for training the artificial intelligence model may be optimized, and performance of the artificial intelligence model may be improved.

FIG. 11 is an example diagram of an input and an output of an artificial intelligence model AIM.

Referring to FIG. 11, an input of the artificial intelligence model AIM may include the first measurement data and at least one piece of density data. The first measurement data may include a measurement result of measuring, by the metrology device 20, the first semiconductor chip with the CMP process completed thereon by using the PWG metrology method, that is, a step height CMP step height value of the target region. The number of pieces of the scalar data representing the step height CMP step height value may be about 500,000, and about 500,000 pieces of the scalar data may be included in the first measurement data. The size of the target region of the first measurement data may be referred to as an input unit domain size. For example, the size of the target region may be about 40 μm*about 40 μm. A particular density data may include an image of a particular layout, to which the layout density has been applied, among a plurality of layouts included in the first semiconductor chip. Each of first through sixth density data density data 1 through density data 6 illustrated as an example in FIG. 11 may include the layout density of lower layers on a surface processed by the CMP process per module of the first semiconductor layer. For example, the first density data density data 1 may include an image of the first layout of the first semiconductor chip, to which the layout density is applied (or an image of layers included in the first layout). The second density data density data 2 may include an image of the second layout of the first semiconductor chip, to which the layout density is applied (or an image of layers included in the second layout). Similarly, each of the third through sixth density data density data 3 through density data 6 may include an image of each of the third through sixth layouts of the fourth semiconductor chip to which the layout density is applied. However, the implementation is not limited thereto. The first through sixth layouts may have different types of layers included in the layout or different critical dimension (CD) ranges. In some implementations, the density data included in the input of the artificial intelligence model AIM may correspond to the first measurement data. For example, the layout included in the image of the density data may correspond to the layout of the first semiconductor chip on which the CMP process has been performed. At least one piece of density data may be included in the input of the artificial intelligence model AIM. For example, at least one piece of density and the first measurement data of the first through sixth density data density data 1 through density data 6 may be input to the artificial intelligence model AIM. In some implementations, the size of an image included in each piece of density data may be greater than or equal to the size of the target region (for example, about 40 μm*about 40 μm). For example, the domain of each piece of density data may be about 40 μm to about 120 μm, but is not limited thereto.

The output of the artificial intelligence model AIM may include the second measurement data. The second measurement data may include a step height CMP step height value with metal deposition of the target region in the second semiconductor chip. The number of pieces of scalar data representing the step height CMP step height value with metal deposition may be about 500,000. The size of the target region of the second measurement data may be referred to as an output unit domain size.

According to the implementation described above, the degree of accurate prediction of the artificial intelligence model may be improved, by learning and applying the density data considering a particular layout periphery to the artificial intelligence model.

FIG. 12 is a diagram illustrating an example of the artificial intelligence model AIM.

Referring to FIGS. 11 and 12, the artificial intelligence model AIM may include a neural network. The neural network may include an input layer, a hidden layer, and an output layer. The input layer may include a layer to which an input of the artificial intelligence model input of ai model is input. The input of the artificial intelligence model input of ai model may include the first measurement data of a full chip and the density data of layouts. For example, the full chip may mean the entire first semiconductor chip. The density data of the layouts may include image of layouts to which the layout density is applied in the first semiconductor chip. The output layer may include a layer to which an output of the artificial intelligence model output of ai model is input. The output of the artificial intelligence model output of ai model may include the second measurement data of a full chip. The second measurement data may include step heights optically measured in a full chip from which the optical interference has been removed. With respect to the second measurement data of the full chip, the full chip may mean the entire semiconductor chip with a metal deposited thereon. The hidden layer may include a plurality of layers included between the input layer and the output layer. In some implementations, the hidden layer may include a fully connected layer FCL, and a regression layer RL. The convolution neural network CNN may include one or more convolution layers and pooling layers.

In some implementations, the artificial intelligence model AIM may be implemented as the convolution neural network CNN, the fully connected layer FCL, exponential linear unit (ELU) activation, L2 regularization, dropout, and a deep regression model including a deeper dense layer.

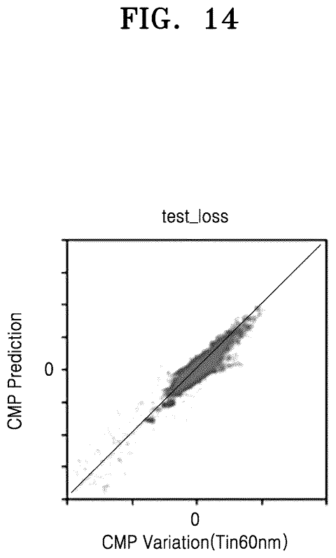

FIG. 13 is an example graph of step heights of a semiconductor chip with a metal deposited thereon. FIG. 14 is an example graph of step heights of a semiconductor chip with a metal deposited thereon and predict values of an artificial intelligence model.

Referring to FIG. 13, the metal is assumed to include TiN. The variation value of a step due to the CMP process on a semiconductor chip with TiN not deposited thereon (for example, refer to ‘CMP variation (TiN 0 nm)’ in FIG. 13), and the distribution of the variation value of a step due to the CMP process on each of the semiconductor chips with TiN deposited thereon (for example, refer to ‘CMP variation (TiN 60 nm)’ in FIG. 13) may have non-linear shapes.

Referring to FIG. 14, the variation value of a step due to the CMP process on each of the semiconductor chips with a metal deposited thereon (for example, refer to ‘CMP variation (TiN 60 nm)’ in FIG. 14), and the distribution of a prediction value of the artificial intelligence model (for example, refer to ‘CMP prediction’ in FIG. 14) may have linear shapes.

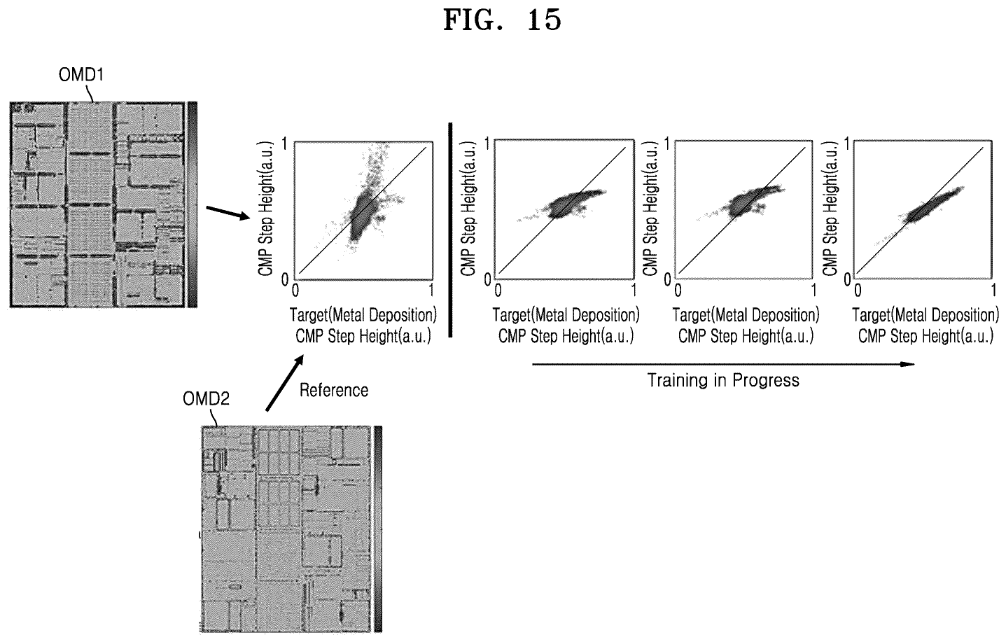

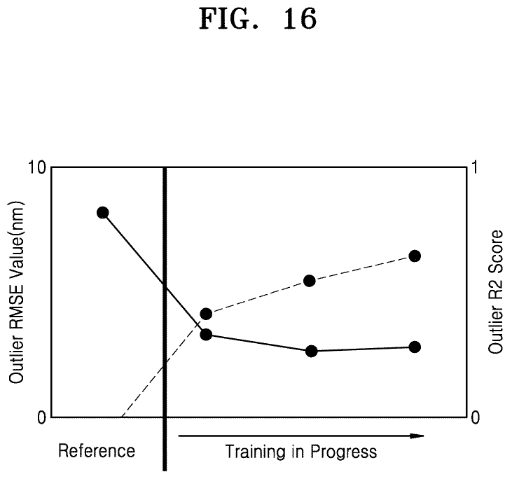

FIG. 15 illustrates diagrams for explaining an example of a learning process of an artificial intelligence model. FIG. 16 is an example diagram of a root mean squared error (RMSE) and an r-squared (R2) score according to a learning process of the artificial intelligence model of FIG. 15.

Referring to FIGS. 13 through 16, the processor 100 may train the artificial intelligence model to learn the learning data set including the first measurement data OMD1, the density data, and the second measurement data OMD2. About 500,000 learning data sets per one semiconductor chip may be set. The learning method may include, for example, the supervised learning, but is not limited thereto. The second measurement data OMD2 may include step heights optically measured by using the PWG metrology method on the semiconductor chip with a metal deposited thereon. In FIG. 15, references based on the first measurement data OMD1 and the second measurement data OMD2 are illustrated as examples. The reference may have a non-linear shape similar to as illustrated in FIG. 13.

When the learning process of the artificial intelligence model (for example, refer to ‘training in progress’ in FIG. 15) is performed, similarly to as illustrated in FIG. 14, step heights of a semiconductor chip with a metal deposited thereon and prediction values of the artificial intelligence model may linearly correspond to each other.

On the other hand, the processor 100 may train the artificial intelligence model to learn data, in which an absolute value of the CMP step is equal to or greater than a particular value in the learning process of the artificial intelligence model, for strengthening the prediction capability about the weak point.

The RMSE, which is measured while the learning process of the artificial intelligence model (for example, refer to ‘training in progress’ in FIG. 16), may have a tendency of gradual reduction with respect to the RMSE of the reference. On the other hand, the R-squared R2 that is measured, while the learning process of the artificial intelligence model (for example, refer to ‘training in progress’ in FIG. 16) is performed, may gradually increase.

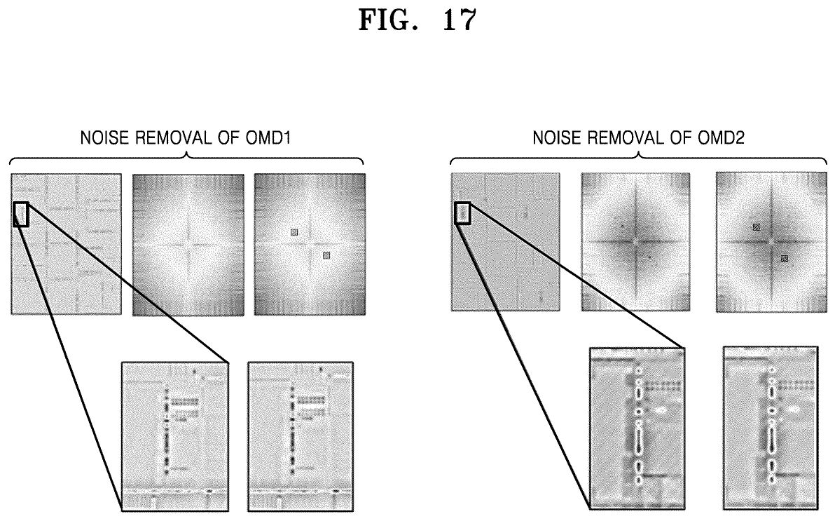

FIG. 17 illustrates example diagrams for explaining an implementation of removal of noise from measurement data in the learning process of the artificial intelligence model in FIG. 15.

Referring to FIGS. 8, 9, 11, 15, and 17, the processor 100 may, when the artificial intelligence model AIM learns according to supervised learning, by using the noise removal algorithm, remove noise from the first raw data of the first measurement data, and noise from the second raw data of the second measurement data. The implementation of removing noise from the first raw data of the first measurement data (for example, refer to ‘noise removal of OMD1’ in FIG. 17) may be the same as the implementation described above with reference to FIG. 8, and the implementation of removing noise from the second raw data of the second measurement data (for example, refer to ‘noise removal of OMD2’ in FIG. 17) may operate similar to the implementation described above with reference to FIG. 8. The R-squared R2 score for a step of the measurement data, from which noise has been removed, compared to a step of the raw data may increase.

The processor 100 according to the implementation may set the first and second measurement data, from which noise has been removed, and the density data, as the learning data set.

In some implementations, the processor 100 may optimize the size of the unit resolution region based on a learning result of the artificial intelligence model. For example, the size of the optimized unit resolution region may be about 2 μm*about 2 μm, but is not limited thereto.

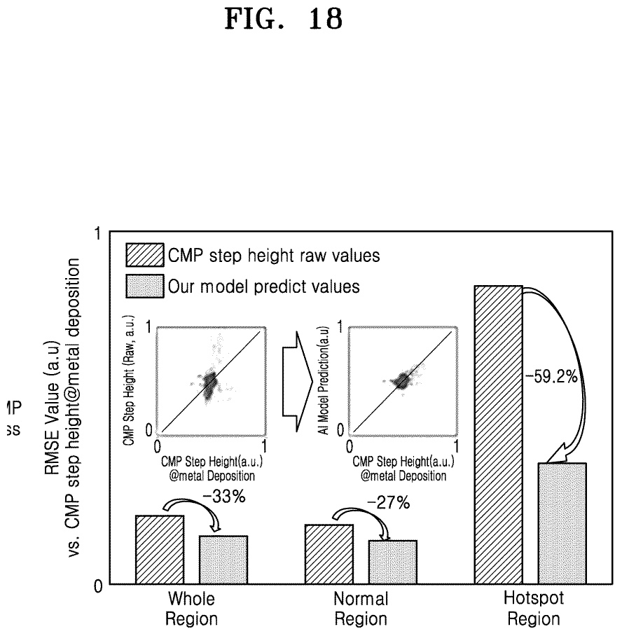

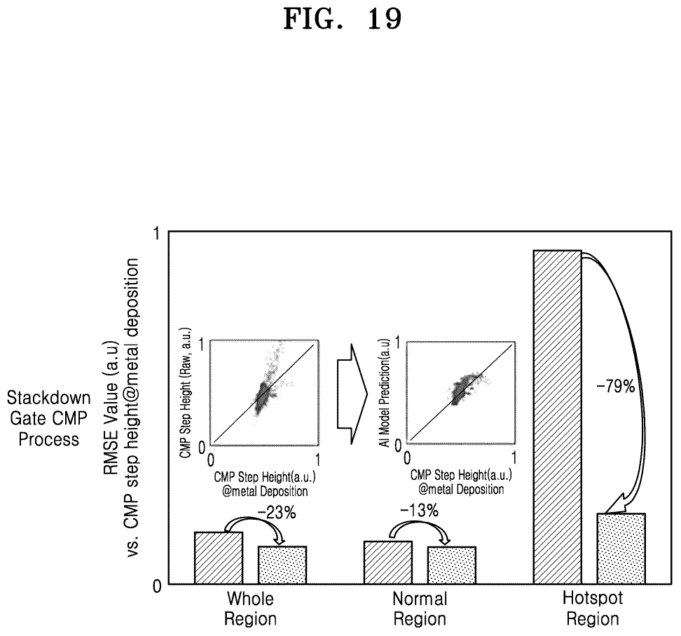

FIGS. 18 and 19 are example diagrams for explaining test results of an artificial intelligence model.

Referring to FIGS. 18 and 19, the number of pieces of test data for testing an artificial intelligence model of the implementations is assumed to be about 200,000.

Referring to FIG. 18, after the test data is applied to the artificial intelligence model of the implementation, the total RMSE has been reduced by about 33.2%. The outlier RSME has been reduced by about 59.2%. For example, in the whole region (for example, refer to ‘whole region’ in FIG. 18), the RMSE of predict value (for example, refer to ‘our model predict values’ in FIG. 18) has been reduced by about 33% with respect to the raw data (for example, refer to ‘CMP step height raw values’ in FIG. 18). In a normal region (for example, refer to ‘normal region’ in FIG. 18), the RSME of the predict values of the artificial intelligence model (for example, refer to ‘our model predict values’ in FIG. 18) has been reduced by about 27% with respect to the raw data (for example, refer to ‘CMP step height raw values’ in FIG. 18). In a hotspot region (for example, refer to ‘hotspot region’ in FIG. 18), the RSME of the predict values of the artificial intelligence model (for example, refer to ‘our model predict values’ in FIG. 18) has been reduced by about 59.2% with respect to the raw data (for example, refer to ‘CMP step height raw values’ in FIG. 18).

Referring to FIG. 19, as a result of applying the test data to the artificial intelligence model of the present disclosure, the consistency of the outlier may be improved, the outlier RSME may be reduced by about 78.6%, and the R-squared R2 score may be increased. For example, in the whole region (for example, refer to ‘whole region’ in FIG. 19), the RMSE of the predict values of the artificial intelligence model may be reduced by about 23%. In the normal region (for example, refer to ‘normal region’ in FIG. 19), the RMSE of the predict values of the artificial intelligence model may be reduced by about 13% with respect to the raw data. In the hotspot region (for example, refer to ‘hotspot region’ in FIG. 19), the RMSE of the predict values of the artificial intelligence model may be reduced by about 79% with respect to the raw data.

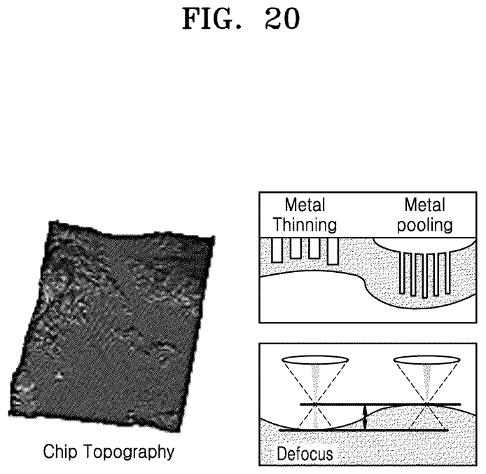

FIG. 20 illustrates example diagrams of weak points.

Referring to FIG. 20, a weak point in an image (for example, refer to ‘chip topography’ in FIG. 20), in which a semiconductor chip is optically measured, may occur on some surface. For example, the weak point may include metal thinning, metal pooling, a concave surface, where the surface is formed in concave and convex shapes to cause defocus, etc. The weak point detection device 50 may detect the weak point of a semiconductor chip by using the second measurement data predicted by the artificial intelligence model AIM.

Terms, such as first and second, described above are used to distinguish one component from another, and the component is not limited by the above-described terms.

Singular expressions include plural expressions unless they are explicitly and exceptionally specified in context.

In each operation, the reference numeral is used for convenience of explanation, the reference numeral does not describe the sequence of operations, and each operation may be carried out differently from the specified sequence unless a particular sequence is clearly stated in the context.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

It will be clearly understood by the one of ordinary skill in the art that the structure of the present disclosure may be variously modified or changed without departing from the scope or the technical idea of the present disclosure. Considering the descriptions given above, when the modifications and changes to the present disclosure fall within the scope of the claims and equivalents below, it will be considered that the present disclosure includes the modifications and changes to the present disclosure.

While the present disclosure has been particularly shown and described with reference to implementations thereof, it will be understood that various changes in form and details may be made therein without departing from the spirit and scope of the following claims.

1. A device for transforming measurement data, the device comprising:
a communicator configured to
receive first measurement data, the first measurement data including a plurality of step height values, wherein the plurality of step height values are optically measured in units of a target region on a first semiconductor chip on which a chemical mechanical polishing (CMP) process is performed, and
receive layout data, the layout data including a layout in the first semiconductor chip; and
a processor configured to
based on the layout data, generate density data, the density data including an image to which layout density is applied, the layout density indicating a ratio of area occupied by the layout in a unit resolution region,
input the density data and the first measurement data to an artificial intelligence model, and
predict, as an output of the artificial intelligence model, second measurement data, the second measurement data including a step height value per target region of a second semiconductor chip, the second semiconductor chip comprising the first semiconductor chip and a metal deposited on the first semiconductor chip.

2. The device of claim 1, wherein the processor is configured to
receive raw data of the first measurement data via the communicator,
remove noise from the raw data based on a noise removal algorithm, and
input, to the artificial intelligence model, the first measurement data with the noise removed therefrom.

3. The device of claim 2, wherein the noise removal algorithm comprises fast Fourier transform (FFT), and
wherein the processor is configured to
transform a domain of the raw data to a frequency domain of the FFT based on the FFT,
remove the noise from the raw data based on reflecting at least one mask in FFT spectrum with respect to the raw data, and
transform the frequency domain of the FFT to the domain of the raw data.

4. The device of claim 1, wherein the first measurement data includes one step height value optically measured in one target region, and the density data includes a plurality of images of a plurality of different layouts in the first semiconductor chip.

5. The device of claim 1, wherein a size of the image comprised in the density data is greater than or equal to a size of the target region.

6. The device of claim 1, wherein the artificial intelligence model comprises a neural network, the neural network including an input layer, a hidden layer, and an output layer.

7. The device of claim 6, wherein the hidden layer comprises a convolution layer, a pooling layer, a fully connected layer, and a regression layer.

8. The device of claim 1, wherein the processor is configured to train the artificial intelligence model with a learning data set based on supervised learning, the learning data set comprising the first measurement data, the density data, and the second measurement data.

9. The device of claim 8, wherein the processor is configured to
based on the artificial intelligence model learning according to the supervised learning, remove, based on a noise removal algorithm, noise from first raw data of the first measurement data and remove, based on the noise removal algorithm, noise from second raw data of the second measurement data, and
set, as the learning data set, the first measurement data with noise removed therefrom, the density data, and the second measurement data with noise removed therefrom.

10. The device of claim 8, wherein the processor is configured to optimize a size of a unit resolution region based on a learning result of the artificial intelligence model.

11. A method of transforming measurement data, the method comprising:
receiving first measurement data, the first measurement data including a plurality of step height values, wherein the plurality of step height values are optically measured in units of a target region on a first semiconductor chip on which a chemical mechanical polishing (CMP) process is performed;
receiving layout data, the layout data including a layout in the first semiconductor chip;
generating density data, the density data including an image to which layout density is applied, the layout density indicating a ratio of area occupied by the layout in a unit resolution region; and
predicting, based on an artificial intelligence model and from the density data and the first measurement data, second measurement data, the second measurement data including a step height value per target region of a second semiconductor chip, the second semiconductor chip comprising the first semiconductor chip and a metal deposited on the first semiconductor chip.

12. The method of claim 11, further comprising:
removing noise from raw data of the first measurement data based on a noise removal algorithm; and
generating the first measurement data with the noise removed therefrom.

13. The method of claim 11, wherein the density data includes a plurality of images of a plurality of different layouts in the first semiconductor chip.

14. The method of claim 11, wherein the artificial intelligence model is implemented as a neural network, the neural network comprising an input layer, a convolution layer, a pooling layer, a fully connected layer, a regression layer, and an output layer.

15. The method of claim 14, further comprising training the artificial intelligence model with a learning data set based on supervised learning, the learning data set including the first measurement data, the density data, and the second measurement data.

16. A system comprising:
an optical measurement device configured to generate first measurement data, the first measurement data including a plurality of step height values in units of a target region on a first semiconductor chip by optically measuring the first semiconductor chip on which a chemical mechanical polishing (CMP) process is performed;
a database configured to store layout data, the layout data including a layout in the first semiconductor chip; and
a measurement data transformation device configured to
generate, based on the layout data, density data, and
transform, based on the first measurement data, the density data, and an artificial intelligence model, the first measurement data to second measurement data, the second measurement data including a plurality of step height values of a second semiconductor chip, the second semiconductor chip comprising the first semiconductor chip and a metal deposited on the first semiconductor chip.

17. The system of claim 16, wherein the measurement data transformation device is configured to
generate layout density, the layout density indicating a ratio of an area occupied by the layout in a unit resolution region, and
predict, based on an artificial intelligence model, the second measurement data as an output of the artificial intelligence model from the density data and the first measurement data.

18. The system of claim 16, wherein the measurement data transformation device is configured to
remove noise from raw data of the first measurement data based on a noise removal algorithm, and
input, to the artificial intelligence model, the first measurement data with the noise removed therefrom and the density data.

19. The system of claim 16, wherein the first measurement data comprises one step height value optically measured in one target region, and the density data comprising a plurality of images of a plurality of different layouts in the first semiconductor chip.

20. The system of claim 16, wherein the measurement data transformation device is configured to train the artificial intelligence model with a learning data set based on supervised learning, the learning data set comprising the first measurement data, the density data, and the second measurement data.

21.-25. (canceled)
